(19) United States
(12) Patent Application Publication
(10) Pub. No.: US 2021/0335918 A1
(43) Pub. Date: Oct. 28, 2021

(54) DISPLAY PANEL AND ELECTRONIC DEVICE

(71) Applicant: HUIZHOU CHINA STAR OPTOELECTRONICS TECHNOLOGY CO., LTD., Huizhou (CN)

(72) Inventor: Xiaohong JING, Huizhou, Guangdong (CN)

(21) Appl. No.: 16/615,380

(22) PCT Filed: Sep. 20, 2019
(86) PCT No.: PCT/CN2019/106946

§ 371 Date: Nov. 20, 2019

(30) Foreign Application Priority Data
Jul. 4, 2019 (CN) 201910597423.9

(51) Int. Cl. H01L 27/32; H01L 25/16; G02F 1/13357

(52) U.S. Cl. CPC H01L 27/3232; H01L 25/167; G02F 1/1368; H01L 27/3244; G02F 1/133615

(57) ABSTRACT

A display panel and an electronic device. The display panel includes a thin film transistor layer and a first display area and a second display area disposed on the thin film transistor layer, the second display area surrounding the first display area. The first display area comprises a plurality of first pixel units and a plurality of transparent units arranged alternately, and light emitting structures in the first pixel units are organic light emitting diodes. The second display area comprises a liquid crystal display structure.

### CROSS REFERENCE TO RELATED APPLICATION

This application claims the priority of International Application No. PCT/CN2019/106946, filed on 2019 Sep. 20, which claims priority to Chinese Application No. 201910597423.9, filed on 2019 Jul. 4. The entire disclosures of each of the above applications are incorporated herein by reference.

### BACKGROUND OF INVENTION

### Field of Invention

The present invention relates to the field of display technologies, and in particular, to a display panel and electronic device.

### Description of Prior Art

In the prior art, solutions that makes a screen ratio of a display panel greater than 90%, include a telescopic camera and a hole camera. Both of these solutions can greatly increase the screen ratio of the display panel.

### Technical Problem

However, telescopic cameras require additional mechanical telescoping and control circuitry within the display panel while maintaining the reliability of the mechanical telescoping device, therefore, manufacturing cost is greatly increased. Display panels with hole cameras need to open a hole in the display area of the display panel, and the camera is placed in the opening. This design destroys symmetry and integrity of the display panel itself, reducing aesthetics of the display panel.

### SUMMARY OF INVENTION

The application provides a display panel and an electronic device to increase the screen ratio of the display panel.

In order to solve the above problems, the present application provides a display panel, wherein the display panel comprises a thin film transistor layer and a first display area and a second display area disposed on the thin film transistor layer, the second display area surrounding the first display area;

wherein the first display area comprises a plurality of first pixel units and a plurality of transparent units arranged alternately, and light emitting structures in the first pixel units are organic light emitting diodes;

wherein the second display area comprises a liquid crystal display structure.

According to one aspect of the application, wherein a portion of a side of the second display area overlaps with a portion of a side of the display panel.

According to one aspect of the application, wherein the display panel and the first display area are rectangular, the display panel comprises a first long side and a second long side adjacent to the first long side, the first display area comprises a first short side and a second short side adjacent to the first short side;

wherein the first long side and the first short side overlap, the second long side and the second short side overlap.

According to one aspect of the application, wherein the first display area further comprises a third short side and a fourth short side, the third short side overlaps with a portion of a side of the second display area, the fourth short side overlaps with another side of the second display area.

According to one aspect of the application, wherein a sum of areas of projections of the first pixel units on the thin film transistor layer is less than or equal to a sum of areas of projections of the transparent units on the thin film transistor layer.

According to one aspect of the application, wherein the thin film transistor layer comprises a metal relief region corresponding to the first display area, projections of the transparent units on the thin film transistor layer separates from metal layers of thin film transistors in the metal relief region.

According to one aspect of the application, wherein the liquid crystal display structure constituting the second display area comprises a backlight structure, and the backlight structure is a side-entry backlight structure.

According to one aspect of the application, wherein the side-entry backlight structure comprises a backplane and a light source, wherein the light source is an array of micro light emitting diodes.

According to one aspect of the application, wherein the side-entry backlight structure is distributed on a first long side of the display panel and a third long side corresponding to the first long side.

The present application further provides an electronic device comprising a display panel and a light sensing unit, wherein the display panel comprises a thin film transistor layer and a first display area and a second display area disposed on the thin film transistor layer, the second display area surrounding the first display area;

wherein the first display area comprises a plurality of first pixel units and a plurality of transparent units arranged alternately, and light emitting structures in the first pixel units are organic light emitting diodes;

wherein the second display area comprises a liquid crystal display structure.

According to one aspect of the application, wherein the light sensing unit is a camera.

According to one aspect of the application, wherein when an imaging function of the electronic device is turned off, the second display area is in a display state;

when the imaging function of the display panel is turned on, the second display area is in a transparent state.

According to one aspect of the application, wherein a portion of a side of the second display area overlaps with a portion of a side of the electronic device.

According to one aspect of the application, wherein the electronic device and the first display area are rectangular, the electronic device comprises a first long side and a second long side adjacent to the first long side, the first display area comprises a first short side and a second short side adjacent to the first short side;

wherein the first long side and the first short side overlap, the second long side and the second short side overlap.

According to one aspect of the application, wherein the first display area further comprises a third short side and a fourth short side, the third short side overlaps with a portion of a side of the second display area, the fourth short side overlaps with another side of the second display area.

According to one aspect of the application, wherein a sum of areas of projections of the first pixel units on the thin film transistor layer is less than or equal to a sum of areas of projections of the transparent units on the thin film transistor layer.

According to one aspect of the application, wherein the thin film transistor layer comprises a metal relief region corresponding to the first display area, projections of the transparent units on the thin film transistor layer separates from metal layers of thin film transistors in the metal relief region.

According to one aspect of the application, wherein the liquid crystal display structure constituting the second display area comprises a backlight structure, and the backlight structure is a side-entry backlight structure.

According to one aspect of the application, wherein the side-entry backlight structure comprises a backplane and a light source, wherein the light source is an array of micro light emitting diodes.

According to one aspect of the application, wherein the side-entry backlight structure is distributed on a first long side of the electronic device and a third long side corresponding to the first long side.

### Beneficial Effects

The present application provides a display panel including a first display area composed of a liquid crystal display structure and a second display area composed of an organic light emitting diode display mechanism. The second display area is transparent and when an imaging function of the display panel is closed, the second display area can be combined with the first display area to implement a display function. When the imaging function of the display panel is turned on, the second display area enables light to pass through the area to implement the imaging function. The design of the present application greatly improves the screen ratio of the display panel and realizes a comprehensive screen actually.

### BRIEF DESCRIPTION OF DRAWINGS

FIG. 1 is a structural diagram of a display panel in a first embodiment of the present application.

FIG. 2 is a structural diagram of a display panel in a second embodiment of the present application.

FIG. 3 is a structural diagram of a display panel in a third embodiment of the present application.

FIG. 4 is a cross-sectional view of the display panel of FIG. 1.

FIG. 5 is a partial enlarged view of FIG. 4.

### DETAILED DESCRIPTION OF PREFERRED EMBODIMENTS

Description of following embodiment, with reference to accompanying drawings, is used to exemplify specific embodiments which may be carried out in the present disclosure. Directional terms mentioned in the present disclosure, such as “top”, “bottom”, “front”, “back”, “left”, “right”, “inside”, “outside”, “side”, etc., are only used with reference to orientation of the accompanying drawings. Therefore, the directional terms are intended to illustrate, but not to limit, the present disclosure. In the drawings, components having similar structures are denoted by same numerals.

In order to solve the above problems, the present application provides a display panel, to improve the display ratio of the display panel.

Referring to FIG. 1, the present application provides a display panel, wherein the display panel includes a thin film transistor layer and a first display area 20 and a second display area 10 disposed on the thin film transistor layer, the second display area 10 surrounding the first display area.

Referring to FIG. 5, the first display area 20 includes a plurality of first pixel units 213 and a plurality of transparent units 212 arranged alternately, and light emitting structures 213 in the first pixel units are organic light emitting diodes. The second display area 10 comprises a liquid crystal display structure.

In order to ensure that the light transmittance of the first display area 20 reaches the light sensing requirement of the light sensing unit, a sum of areas of projections of the plurality of first pixel units 213 on the thin film transistor layer is less than or equal to a sum of areas of projections of the plurality of transparent units 212 on the thin film transistor layer.

Referring to FIG. 4, in order to prevent metal structures in the thin film transistor from blocking the light, the thin film transistor layer includes a first thin film transistor layer 110 and a metal relief region 111 corresponding to the first display area. A shape and an area of the metal relief region 111 are the same as a shape and an area of the second display area 10. A projection of the plurality of transparent units 212 on the thin film transistor layer separates from the metal layers of the plurality of thin film transistors in the metal relief region 111.

Referring to FIG. 1, a portion of a side of the second display area 10 overlaps with a portion of a side of the display panel. The display panel and the first display area 20 are rectangular, the display panel comprises a first long side 11 and a second long side 12 adjacent to the first long side, the first display area 20 comprises a first short side 21 and a second short side 22 adjacent to the first short side 21. The first long side 11 and the first short side 21 overlap, the second long side 12 and the second short side 22 overlap. The first display area 20 further comprises a third short side 23 and a fourth short side 24, the third short side 23 overlaps with a portion of a side of the second display area 10, the fourth short side 24 overlaps with another side of the second display area 10.

Since the light emitting structures of the first display area 20 and the second display area 10 are different, the connection structure between them is complicated. This arrangement minimizes an area of the side where the first display area 20 and the second display area 10 overlap, which can reduce the manufacturing difficulty and the manufacturing cost.

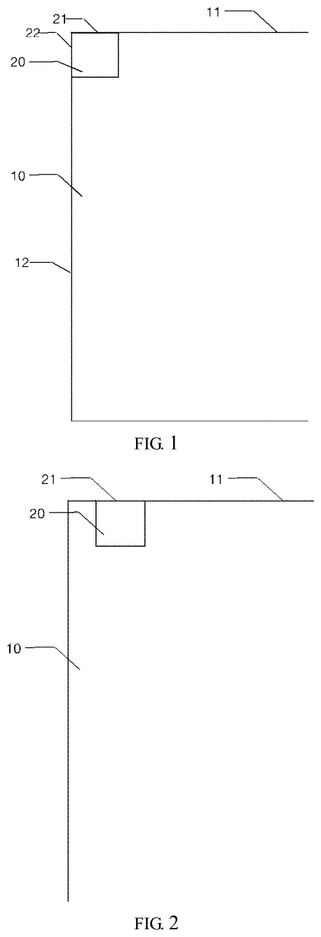

Referring to FIG. 2, the first short side 21 of the second display area 10 in FIG. 2 overlaps with the first long side 11 of the display panel. Compared with the technical solution in FIG. 1, the display panel in this embodiment has a higher manufacturing cost. However, since the second display area 10 is relatively centered, an imaging range of a camera in this solution is relatively large. In practice, the position of the second display area 10 can be set as needed.

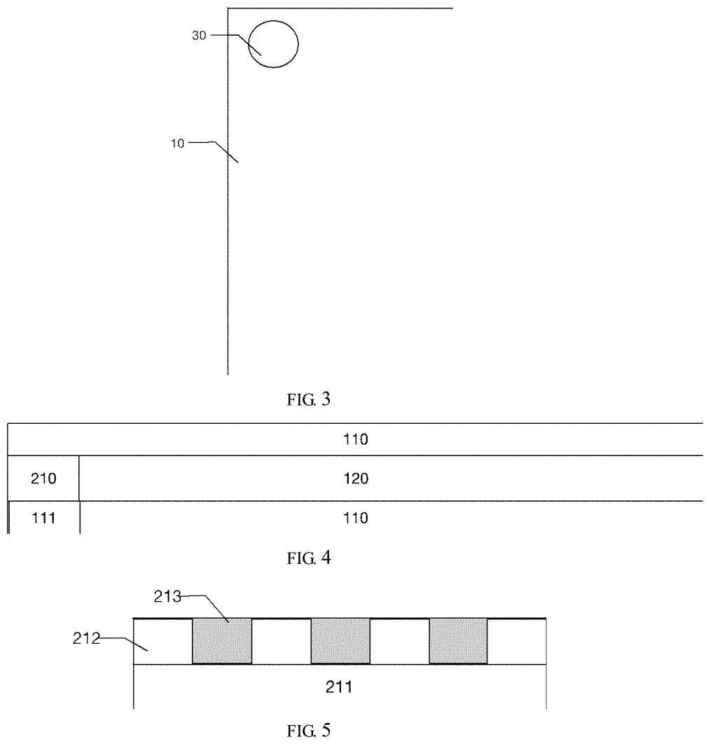

Of course, the shape of the display panel and the second display area 10 is not limited to a rectangle, and can be any shape such as a circle, a triangle, a polygon, or the like. Referring to FIG. 3, in the embodiment, the second display area 30 is circular.

In the present application, the liquid crystal display structure constituting the second display area 10 includes a backlight structure which is a side-entry backlight structure. The side-entry backlight structure includes a back plate and a light source, wherein the light source is a miniature light emitting diode array. The side-entry backlight structure is distributed on the first long side 11 of the display panel and a third long side corresponding to the first long side 11.

The present application further provides an electronic device comprising a display panel and a light sensing unit, wherein the display panel comprises a thin film transistor layer and a first display area and a second display area disposed on the thin film transistor layer, the second display area surrounding the first display area. The first display area comprises a plurality of first pixel units and a plurality of transparent units arranged alternately, and light emitting structures in the first pixel units are organic light emitting diodes. The second display area comprises a liquid crystal display structure.

In the present application, the light sensing unit is a camera. When the imaging function of the electronic device is turned off, the second display area 10 is in a display state. When the imaging function of the display panel is turned on, the second display area 10 is in a transparent state.

The present application provides a display panel including a first display area composed of a liquid crystal display structure and a second display area composed of an organic light emitting diode display mechanism. The second display area is transparent and when an imaging function of the display panel is closed, the second display area can be combined with the first display area to implement a display function. When the imaging function of the display panel is turned on, the second display area enables light to pass through the area to implement the imaging function. The design of the present application greatly improves the screen ratio of the display panel and realizes a comprehensive screen actually.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

1. A display panel, wherein the display panel comprises a thin film transistor layer and a first display area and a second display area disposed on the thin film transistor layer, the second display area surrounding the first display area;
wherein the first display area comprises a plurality of first pixel units and a plurality of transparent units arranged alternately, and light emitting structures in the first pixel units are organic light emitting diodes;
wherein the second display area comprises a liquid crystal display structure.

2. The display panel according to claim 1, wherein a portion of a side of the second display area overlaps with a portion of a side of the display panel.

3. The display panel according to claim 2, wherein the display panel and the first display area are rectangular, the display panel comprises a first long side and a second long side adjacent to the first long side, the first display area comprises a first short side and a second short side adjacent to the first short side;
wherein the first long side and the first short side overlap, the second long side and the second short side overlap.

4. The display panel according to claim 3, wherein the first display area further comprises a third short side and a fourth short side, the third short side overlaps with a portion of a side of the second display area, the fourth short side overlaps with another side of the second display area.

5. The display panel according to claim 1, wherein a sum of areas of projections of the first pixel units on the thin film transistor layer is less than or equal to a sum of areas of projections of the transparent units on the thin film transistor layer.

6. The display panel according to claim 1, wherein the thin film transistor layer comprises a metal relief region corresponding to the first display area, projections of the transparent units on the thin film transistor layer separates from metal layers of thin film transistors in the metal relief region.

7. The display panel according to claim 1, wherein the liquid crystal display structure constituting the second display area comprises a backlight structure, and the backlight structure is a side-entry backlight structure.

8. The display panel according to claim 7, wherein the side-entry backlight structure comprises a backplane and a light source, wherein the light source is an array of micro light emitting diodes.

9. The display panel according to claim 7, wherein the side-entry backlight structure is distributed on a first long side of the display panel and a third long side corresponding to the first long side.

10. An electronic device comprising a display panel and a light sensing unit, wherein the display panel comprises a thin film transistor layer and a first display area and a second display area disposed on the thin film transistor layer, the second display area surrounding the first display area;
wherein the first display area comprises a plurality of first pixel units and a plurality of transparent units arranged alternately, and light emitting structures in the first pixel units are organic light emitting diodes;
wherein the second display area comprises a liquid crystal display structure.

11. The electronic device according to claim 10, wherein the light sensing unit is a camera.

12. The electronic device according to claim 11, wherein when an imaging function of the electronic device is turned off, the second display area is in a display state;
when the imaging function of the display panel is turned on, the second display area is in a transparent state.

13. The electronic device according to claim 10, wherein a portion of a side of the second display area overlaps with a portion of a side of the electronic device.

14. The electronic device according to claim 11, wherein the electronic device and the first display area are rectangular, the electronic device comprises a first long side and a second long side adjacent to the first long side, the first display area comprises a first short side and a second short side adjacent to the first short side;
wherein the first long side and the first short side overlap, the second long side and the second short side overlap.

15. The electronic device according to claim 12, wherein the first display area further comprises a third short side and a fourth short side, the third short side overlaps with a portion of a side of the second display area, the fourth short side overlaps with another side of the second display area.

16. The electronic device according to claim 10, wherein a sum of areas of projections of the first pixel units on the thin film transistor layer is less than or equal to a sum of areas of projections of the transparent units on the thin film transistor layer.

17. The electronic device according to claim 10, wherein the thin film transistor layer comprises a metal relief region corresponding to the first display area, projections of the transparent units on the thin film transistor layer separates from metal layers of thin film transistors in the metal relief region.

18. The electronic device according to claim 10, wherein the liquid crystal display structure constituting the second display area comprises a backlight structure, and the backlight structure is a side-entry backlight structure.

19. The electronic device according to claim 18, wherein the side-entry backlight structure comprises a backplane and a light source, wherein the light source is an array of micro light emitting diodes.

20. The electronic device according to claim 18, wherein the side-entry backlight structure is distributed on a first long side of the electronic device and a third long side corresponding to the first long side.
